(19) United States
(12) Patent Application Publication
(10) Pub. No.: US 2025/0393477 A1
(43) Pub. Date: Dec. 25, 2025

(54) MRAM WITH RECESSED ELECTRODES

(71) Applicant: International Business Machines Corporation, Armonk, NY (US)

(72) Inventors: Oscar van der Straten, Guilderland Center, NY (US); Chih-Chao Yang, Glenmont, NY (US)

(21) Appl. No.: 18/754,117

(22) Filed: Jun. 25, 2024

(51) Int. Cl. H10N 50/10; H10B 61/00; H10N 50/01; H10N 50/80

(52) U.S. Cl. CPC H10N 50/10; H10B 61/00; H10N 50/01; H10N 50/80

(57) ABSTRACT

A semiconductor device is provided. The semiconductor device includes a memory including a bottom electrode, a magnetic tunnel junction (MTJ) stack on the bottom electrode, and an upper electrode on the MTJ stack. The semiconductor device also includes at least one dielectric layer formed around the memory, wherein a top metal layer contact hole is formed in the at least one dielectric layer, a dielectric liner layer formed in the top metal contact hole, and a top metal layer contact in the top metal layer contact hole.

### BACKGROUND

The present disclosure relates to magnetic random-access memory (MRAM) devices based on magnetic tunnel junction (MTJ) structures. Certain MRAM devices may be fabricated to include a bottom electrode, an MRAM stack, and a top electrode. In general, MRAM devices may be used in a variety of applications. One example application is embedded storage (e.g., eFlash replacement). Another example is cache (e.g., embedded dynamic random-access memory (eDRAM), or static random-access memory (SRAM)). Preventing electrical shorting among various layers of the memory device may be desirable.

Embodiments of the present disclosure relate to a semiconductor device. The semiconductor device includes a memory. The memory includes a bottom electrode, a magnetic tunnel junction (MTJ) stack on the bottom electrode, and an upper electrode on the MTJ stack. Also, the bottom electrode and the top electrode each include a dielectric core.

Other embodiments relate to a semiconductor device including a memory. The memory includes a bottom electrode, a magnetic tunnel junction (MTJ) stack on the bottom electrode, and an upper electrode on the MTJ stack. In embodiments, a width of the MTJ stack is greater than a width of bottom electrode and greater than a width of the top electrode.

Other embodiments relate to a method of manufacturing a semiconductor device. The method includes forming a first portion of a dielectric fill layer. The method further includes forming a bottom electrode in the first portion of the dielectric fill layer. The method further includes forming a magnetic tunnel junction (MTJ) stack on the bottom electrode. The method further includes forming a second portion of the dielectric fill layer on the first portion of the dielectric fill layer and on the MTJ stack. The method further includes forming a top electrode on the MTJ stack in the second portion of the dielectric fill layer. The method further includes forming a third portion of the dielectric fill layer on the second portion of the dielectric fill layer and on the top electrode.

The above summary is not intended to describe each illustrated embodiment or every implementation of the present disclosure.

### BRIEF DESCRIPTION OF THE DRAWINGS

The drawings included in the present application are incorporated into, and form part of the specification. They illustrate embodiments of the present disclosure and, along with the description, explain the principles of the disclosure. The drawings are only illustrative of certain embodiments and do not limit the disclosure.

FIG. 1 is a cross-sectional view of a semiconductor device that includes an MRAM device at an intermediate stage of the manufacturing process, according to embodiments.

FIG. 2 is a cross-sectional view of the semiconductor device of FIG. 1 after additional fabrication operations, according to embodiments.

FIG. 3 is a cross-sectional view of the semiconductor device of FIG. 2 after additional fabrication operations, according to embodiments.

FIG. 4 is a cross-sectional view of the semiconductor device of FIG. 3 after additional fabrication operations, according to embodiments.

FIG. 5 is a cross-sectional view of the semiconductor device of FIG. 4 after additional fabrication operations, according to embodiments.

FIG. 6 is a cross-sectional view of the semiconductor device of FIG. 5 after additional fabrication operations, according to embodiments.

FIG. 7 is a cross-sectional view of the semiconductor device of FIG. 6 after additional fabrication operations, according to embodiments.

FIG. 8 is a cross-sectional view of the semiconductor device of FIG. 7 after additional fabrication operations, according to embodiments.

FIG. 9 is a cross-sectional view of the semiconductor device of FIG. 8 after additional fabrication operations, according to embodiments.

FIG. 10 is a cross-sectional view of the semiconductor device of FIG. 9 after additional fabrication operations, according to embodiments.

FIG. 11 is a cross-sectional view of the semiconductor device of FIG. 10 after additional fabrication operations, according to embodiments.

FIG. 12 is a cross-sectional view of the semiconductor device of FIG. 11 after additional fabrication operations, according to embodiments.

FIG. 13 is a cross-sectional view of the semiconductor device of FIG. 12 after additional fabrication operations, according to embodiments.

FIG. 14 is a cross-sectional view of the semiconductor device of FIG. 13 after additional fabrication operations, according to embodiments.

FIG. 15 is a cross-sectional view of the semiconductor device of FIG. 14 after additional fabrication operations, according to embodiments.

FIG. 16 is a cross-sectional view of the semiconductor device of FIG. 15 after additional fabrication operations, according to embodiments.

FIG. 17 is a cross-sectional view of the semiconductor device of FIG. 16 after additional fabrication operations, according to embodiments.

FIG. 18 is a cross-sectional view of the semiconductor device of FIG. 17 after additional fabrication operations, according to embodiments.

FIG. 19 is a cross-sectional view of the semiconductor device of FIG. 18 after additional fabrication operations, according to embodiments.

FIG. 20 is a cross-sectional view of the semiconductor device of FIG. 19 after additional fabrication operations, according to embodiments.

FIG. 21 is a cross-sectional view of the semiconductor device of FIG. 20 after additional fabrication operations, according to embodiments.

FIG. 22 is a cross-sectional view of the semiconductor device of FIG. 21 after additional fabrication operations, according to embodiments.

FIG. 23 is a cross-sectional view of the semiconductor device of FIG. 22 after additional fabrication operations, according to embodiments.

FIG. 24 is a cross-sectional view of the semiconductor device of FIG. 23 after additional fabrication operations, according to embodiments.

FIG. 25 is a cross-sectional view of the semiconductor device of FIG. 24 after additional fabrication operations, according to embodiments.

### DETAILED DESCRIPTION

The present disclosure describes MRAM devices including magnetic tunnel junction (“MTJ”) stacks and methods of manufacturing MRAM devices. In particular, the present disclosure describes MRAM devices and methods of manufacturing same, the MRAM devices including a top and/or bottom electrode structure having a hollowed-out center portion filled with a dielectric material.

According to a first aspect of the invention, there is provided a semiconductor device comprising a memory. The memory includes a bottom electrode, a magnetic tunnel junction (MTJ) stack on the bottom electrode, and an upper electrode on the MTJ stack. Also, the bottom electrode and the top electrode each include a dielectric core. This may allow for a dielectric fill layer to be formed without the risk of forming ILD voids. This may further allow for a reduction in the likelihood of electrical shorting between the electrodes and the different layers of the MTJ stack.

In embodiments of the first aspect, a width of the MTJ stack is greater than a width of bottom electrode and greater than a width of the top electrode. This may allow for the sidewalls of the bottom electrode to be covered with an ILD fill layer prior to the patterning of the MTJ stack. This may help to prevent resputtering of the metal materials of the MTJ stack onto the bottom electrode during the patterning.

In embodiments of the first aspect, the bottom electrode and the top electrode have a cylindrical shape. This allows for effective electrical connection with a bottom metal contact.

In embodiments of the first aspect, the dielectric cores have a cylindrical shape. By having the dielectric cores inside the bottom electrode and top electrode, the thickness of the metal portions of the top and bottom electrodes may be reduced. This may allow for a reduction in the occurrence or severity of cupping (or dishing) of the electrodes during a CMP material removal process. This elimination of cupping (or dishing) may further allow for an improvement in the structural integrity of the layers of the MTJ stack, which may lead to improved device performance.

In embodiments of the first aspect, the dielectric cores comprise at least one of Al₂O₃ and TiO₂. The insulating material inside the bottom electrode and top electrode, the thickness of the metal portions of the top and bottom electrodes may be reduced. This may allow for a reduction in the occurrence or severity of cupping (or dishing).

In embodiments of the first aspect, the semiconductor device further includes a dielectric encapsulation layer formed to cover sidewalls of the MTJ stack. This dielectric encapsulation layer may help to prevent resputtering of the metal materials of the MTJ stack during the subsequent patterning of the top electrode.

In embodiments of the first aspect, the semiconductor device further includes a dielectric fill layer formed around the memory and that directly contacts the top electrode and the bottom electrode. The dielectric fill layer may be forming by depositing the ILD material in several different processing steps rather than in a single step. The low aspect ratio (i.e., height to width ratio) of each of the separate ILD deposition steps may help to avoid ILD void formation.

In embodiments of the first aspect, the MTJ stack includes a reference layer, a tunnel barrier layer, and a free layer. This allows for effective functioning of the MRAM device.

In embodiments of the first aspect, the semiconductor device further includes a bottom metal contact electrically connected to the bottom electrode, and a top metal contact electrically connected to the top electrode. This allows for the electrical connection of the MRAM devices with various layers of the BEOL structure.

In embodiments of the first aspect, the semiconductor device further includes a metal cap layer between the bottom metal contact and the bottom electrode. In certain cases, the metal cap layer may function as an inert barrier layer between the underlying bottom metal contact and the bottom electrode of the MRAM stack. Thus, during subsequent processing operations, there is low risk of diffusion of the metal cap layer into other layers of the semiconductor device.

According to a second aspect of the invention, there is provided a semiconductor device comprising a memory. The memory includes a bottom electrode, a magnetic tunnel junction (MTJ) stack on the bottom electrode, and an upper electrode on the MTJ stack. In embodiments, a width of the MTJ stack is greater than a width of bottom electrode and greater than a width of the top electrode. This may allow for the sidewalls of the bottom electrode to be covered with an ILD fill layer prior to the patterning of the MTJ stack. This may help to prevent resputtering of the metal materials of the MTJ stack onto the bottom electrode during the patterning.

In embodiments of the second aspect, the bottom electrode and the top electrode each include a dielectric core. This may allow for a dielectric fill layer to be formed without the risk of forming ILD voids. This may further allow for a reduction in the likelihood of electrical shorting between the electrodes and the different layers of the MTJ stack.

In embodiments of the second aspect, the bottom electrode and the top electrode have a cylindrical shape. This allows for effective electrical connection with a bottom metal contact.

In embodiments of the second aspect, the dielectric cores have a cylindrical shape. By having the dielectric cores inside the bottom electrode and top electrode, the thickness of the metal portions of the top and bottom electrodes may be reduced. This may allow for a reduction in the occurrence or severity of cupping (or dishing) of the electrodes during a CMP material removal process. This elimination of cupping (or dishing) may further allow for an improvement in the structural integrity of the layers of the MTJ stack, which may lead to improved device performance.

In embodiments of the second aspect, the dielectric cores comprise at least one of Al₂O₃ and TiO₂. The insulating material inside the bottom electrode and top electrode, the thickness of the metal portions of the top and bottom electrodes may be reduced. This may allow for a reduction in the occurrence or severity of cupping (or dishing).

In embodiments of the second aspect, the semiconductor device further includes a dielectric encapsulation layer formed to cover sidewalls of the MTJ stack. This dielectric encapsulation layer may help to prevent resputtering of the metal materials of the MTJ stack during the subsequent patterning of the top electrode.

In embodiments of the second aspect, the semiconductor device further includes a dielectric fill layer formed around the memory, the dielectric fill layer directly contacting the top electrode and the bottom electrode. The dielectric fill layer may be forming by depositing the ILD material in several different processing steps rather than in a single step. The low aspect ratio (i.e., height to width ratio) of each of the separate ILD deposition steps may help to avoid ILD void formation.

In embodiments of the second aspect, the MTJ stack includes a reference layer, a tunnel barrier layer, and a free layer. This allows for effective functioning of the MRAM device.

In embodiments of the second aspect, the semiconductor device further includes a bottom metal contact electrically connected to the bottom electrode, and a top metal contact electrically connected to the top electrode. This allows for the electrical connection of the MRAM devices with various layers of the BEOL structure.

In embodiments of the second aspect, the semiconductor device further includes a metal cap layer between the bottom metal contact and the bottom electrode. In certain cases, the metal cap layer may function as an inert barrier layer between the underlying bottom metal contact and the bottom electrode of the MRAM stack. Thus, during subsequent processing operations, there is low risk of diffusion of the metal cap layer into other layers of the semiconductor device.

According to a third aspect of the invention, there is provided a method of manufacturing a semiconductor device. The method includes forming a first portion of a dielectric fill layer. The method further includes forming a bottom electrode in the first portion of the dielectric fill layer. The method further includes forming a magnetic tunnel junction (MTJ) stack on the bottom electrode. The method further includes forming a second portion of the dielectric fill layer on the first portion of the dielectric fill layer and on the MTJ stack. The method further includes forming a top electrode on the MTJ stack in the second portion of the dielectric fill layer. The method further includes forming a third portion of the dielectric fill layer on the second portion of the dielectric fill layer and on the top electrode. The dielectric fill layer may be forming by depositing the ILD material in several different processing steps (i.e., the first portion, the second portion, and the third portion) rather than in a single step. The low aspect ratio (i.e., height to width ratio) of each of the separate ILD deposition steps may help to avoid ILD void formation.

In embodiments of the third aspect, the method further includes forming a dielectric encapsulation layer that covers sidewalls of the MTJ stack. This dielectric encapsulation layer may help to prevent resputtering of the metal materials of the MTJ stack during the subsequent patterning of the top electrode.

In embodiments of the third aspect, the method further includes forming a dielectric core in the bottom electrode and the top electrode. This may allow for a dielectric fill layer to be formed without the risk of forming ILD voids. This may further allow for a reduction in the likelihood of electrical shorting between the electrodes and the different layers of the MTJ stack.

In embodiments of the third aspect, the method further includes forming a top metal contact on the top electrode in the third portion of the dielectric fill layer. This allows for the electrical connection of the MRAM devices with various layers of the BEOL or MOL structures.

In embodiments of the third aspect, a width of the MTJ stack is greater than a width of bottom electrode and greater than a width of the top electrode. This may allow for the sidewalls of the bottom electrode to be covered with an ILD fill layer prior to the patterning of the MTJ stack. This may help to prevent resputtering of the metal materials of the MTJ stack onto the bottom electrode during the patterning.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of elements can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto a surface, such as the surface of a wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film’s electrical and mechanical properties.

Removal/etching is any process that removes material from a surface, such as the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties of a material by doping, for example, transistor sources and drains, generally by diffusion and/or by ion implantation. These doping processes may be followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) may be used to connect and isolate transistors and their components. Selective doping of various regions of the semiconductor substrate allows the conductivity of the substrate to be changed with the application of voltage. By creating structures of these various components, billions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed using a light sensitive polymer called a photo-resist. To build the complex structures that make up a transistor and the many wires that connect the millions of transistors of a circuit, lithography and etch pattern transfer operations are repeated multiple times. Each pattern being formed on the wafer is aligned to the previously formed patterns and slowly the conductors, insulators and selectively doped regions are built up to form the final device.

Turning now to an overview of technologies that are more specifically relevant to aspects of the present disclosure, embedded DRAM (eDRAM) is a dynamic random-access memory (DRAM) integrated on the same die or multi-chip module (MCM) of an application-specific integrated circuit (ASIC) or microprocessor. eDRAM has been implemented in silicon-on-insulator (SOI) technology, which refers to the use of a layered silicon–insulator–silicon substrate in place of conventional silicon substrates in semiconductor manufacturing. eDRAM technology has met with varying degrees of success, and demand for SOI technology as a server memory option has decreased in recent years. Magnetoresistive random-access memory (MRAM) devices using magnetic tunnel junctions (MTJ) are one option to replace existing eDRAM technologies. MRAM is a non-volatile memory, and this benefit is a driving factor that is accelerating the development of this memory technology.

A magnetic tunnel junction (MTJ) device, which is a primary storage element in a magnetic random access memory (MRAM), is a magnetic storage and switching device in which two ferromagnetic layers are separated by a thin insulating oxide layer (i.e., a tunnel barrier layer) to form a stacked structure. The tunnel barrier layer may comprise, for example, magnesium oxide or aluminum oxide. One of the ferromagnetic layers has a magnetization that is fixed, and it is therefore referred to as a magnetic fixed layer (or pinned layer, or reference layer). However, the other ferromagnetic layer has a magnetization that can change, and it is therefore referred to as a free layer (or magnetic free layer). When a bias voltage is applied to the MTJ device, electrons that are spin polarized by the ferromagnetic layers traverse the insulating barrier through a process known as quantum tunneling to generate an electric current whose magnitude depends on an orientation of magnetization of the ferromagnetic layers. The MTJ device will exhibit a low resistance when a magnetic moment of the free layer is parallel to the fixed layer magnetic moment, and it will exhibit a high resistance when the magnetic moment of the free layer is oriented anti-parallel to the fixed layer magnetic moment.

The materials and geometries used to build the stack of different layers forming the MTJ device are factors that affect the characteristics of the device in terms of speed (i.e., switching time) and power consumption (e.g., voltage and/or current required to switch the device from one state to another). As discussed above, certain MTJ devices have a pillar structure (i.e., a stack of materials) having a cylindrical shape, where current flows from a top layer to a bottom layer, or vice versa, in order to switch the magnetization of one ferromagnetic layer. These types of MTJ devices are generally referred to as spin transfer torque (STT) MTJ devices. Certain STT MRAM devices may have limited switching speed and endurance in comparison to static random access memory (SRAM) devices (i.e., random access memory that retains data bits in its memory as long as power is being supplied). Other types of MTJ devices are referred to as spin orbit torque (SOT) devices. In the SOT type of device, the stacked pillar structure is still cylindrically shaped, but the stack is deposited on top of a heavy metal conductor. In the SOT type of MTJ device, current flows horizontally in this conductor and switches the magnetization of the ferromagnetic layer at the interface.

In STT type MRAM devices, the manufacture of the devices is often performed in conjunction with forming middle-of-line (MOL) or back-end-of-line (BEOL) layers. This may be referred to as embedded MRAM, where the MRAM devices are embedded in, or formed in conjunction with these layers. In general, front-end-of-line (FEOL) refers to the set of process steps that form transistors and other circuit elements (such as resistors and capacitors) that are later connected electrically with middle-of-line (MOL) and back-end-of-line (BEOL) layers. In general, MOL refers to the set of wafer processing steps used to create the structures that provide the local electrical connections between transistors (e.g., gate contact formation). MOL processing generally occurs after FEOL processes and before BEOL processes. In general, the BEOL is the portion of IC fabrication where the individual devices (transistors, capacitors, resistors, etc.) are interconnected with wiring on the wafer.

As discussed above, MRAM devices may be useful for a variety of different applications, such as embedded storage and cache. For certain MRAM devices, voids may be inadvertently formed in the interlayer dielectric (ILD) gap fill layers. After MTJ stack patterning, the inter-pillar spaces are filled with ILD to enable a connection to a BEOL wiring by a top contact level. The ILD gap fill between adjacent MTJ pillars presents a significant challenge since the presence of voids in the ILD between the pillars can lead to shorts. However, as described in detail herein, the present embodiments provide a method and structure for forming an electrode structure having a hollow or recessed structure that is filled with a dielectric material. Due to the recessed (or hollowed out) structure of the electrodes, the ILD gap fill layer may be deposited in a series of separate processing steps, with each addition of ILD material having a lowered aspect ratio (the ratio of height to width), and this reduces or eliminates the possibility of forming voids in the gap fill layer.

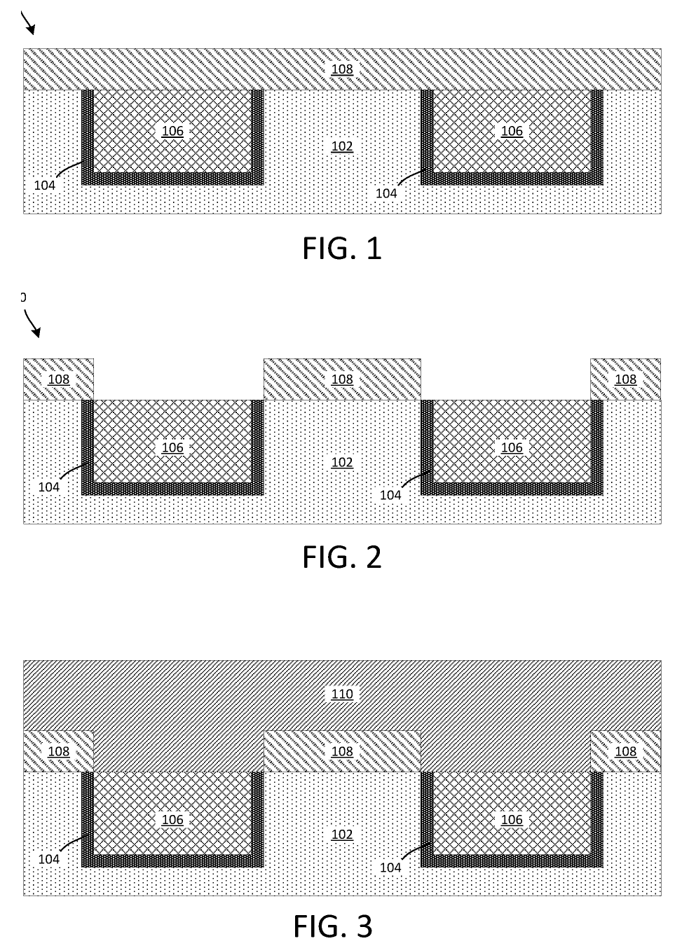

Referring now to the drawings in which like numerals represent the same or similar elements and initially to FIG. 1, an exemplary method of manufacturing a semiconductor device 100 (i.e., an MRAM device) to which the present embodiments may be applied is shown. In certain examples, several back end of line (“BEOL”) layers and front end of line (FEOL) layers may be formed. The BEOL metal layers (not shown) can include, for example, Cu, TaN, Ta, Ti, TiN or a combination thereof. A BEOL dielectric layer (not shown) may be formed on the sides of one or more of the BEOL metal layers. The BEOL dielectric layer may be composed of, for example, SiOₓ, SiNₓ, SiBCN, low-κ, or any other suitable dielectric material. The structure including the FEOL/BEOL layers may be a starting structure upon which the MRAM devices are formed.

As shown in the semiconductor device 100 of FIG. 1, a first ILD layer 102 is formed. Then, a suitable combination of patterning and material removal processes are performed to form bottom metal contact holes. Then, as shown in FIG. 1, a bottom barrier layer 104 is first formed in the bottom metal contact holes. The bottom barrier layer 104 may comprise, for example, Ta or TaN. Then, a bottom metal contact 106 (or bottom metal layer) is deposited on the bottom barrier layer 104 and fills in the remainder of the bottom metal contact hole. This bottom metal contact 106 may be included in one of the BEOL layers. In certain examples, the bottom metal contact 106 (e.g., an M1 level interconnect wire) may include, Cu, Co, Nb, NbN, W, WN, Ta, TaN, Ti, TiN, Ru, Mo, Cr, V, Pd, Pt, Rh, Sc, Al and other metals or conductive metal nitrides. It should be appreciated that the interconnect structure shown in FIG. 1 is merely one example, and any other suitable interconnect structure (e.g., number of layers, size, number of contacts, etc.) may be used. Then, in certain examples, and optional material removal process such as chemical mechanical planarization (CMP) may be performed to planarize the surface of the semiconductor device 100. As shown in FIG. 1, a dielectric cap 108 is formed on the top surfaces of the first ILD layer 102, the bottom barrier layer 104 and the bottom metal contact 106. Certain examples of materials that may be used for the dielectric cap 108 may include SiN and SiCN.

Referring now to FIG. 2, this figure is a cross-sectional view of the semiconductor device 100 of FIG. 1 after additional fabrication operations, according to embodiments. As shown in FIG. 2, suitable patterning and material removal processes are performed on the dielectric cap 108 to expose the top surface of the bottom metal contact 106 (or wiring) without exposing the bottom barrier layer 104 or the first ILD layer 102.

Referring now to FIG. 3, this figure is a cross-sectional view of the semiconductor device 100 of FIG. 2 after additional fabrication operations, according to embodiments. As shown in FIG. 3, a suitable material deposition process is performed to form a metal cap layer 110. The metal cap layer 110 fills in the spaces between the different portions of the dielectric cap 108. In one example, the metal cap layer 110 may comprise tungsten (W). As shown in FIG. 3, the metal cap layer 110 may initially be formed in excess so that a portion of the metal cap layer 110 extends above the top surface of the dielectric cap 108.

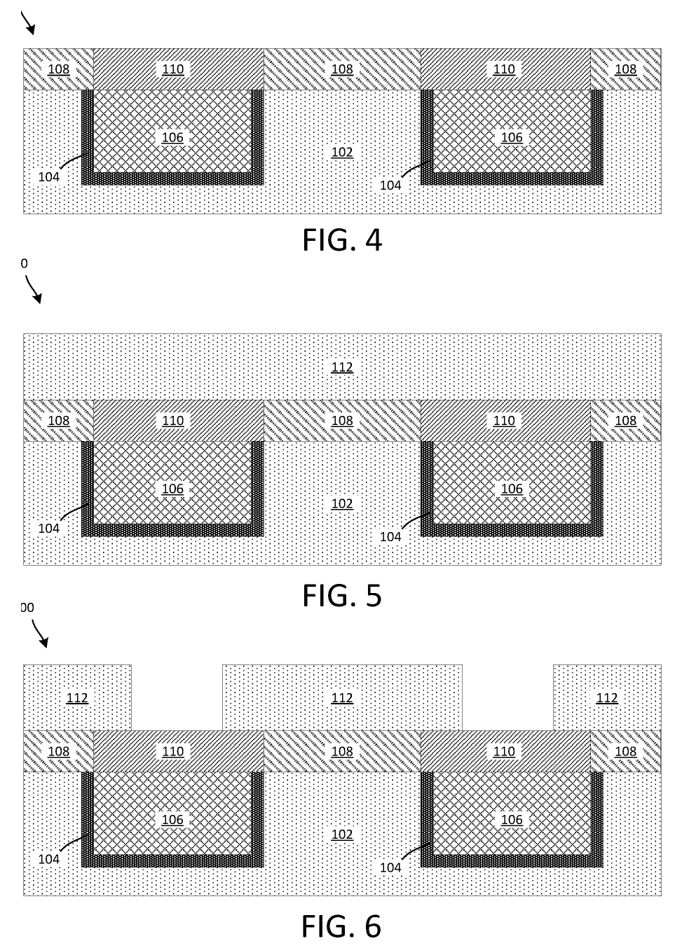

Referring now to FIG. 4, this figure is a cross-sectional view of the semiconductor device 100 of FIG. 3 after additional fabrication operations, according to embodiments. As shown in FIG. 4, a suitable material removal process (e.g., CMP) may be performed to remove any excess material of the metal cap layer 110 and to planarize the upper surface of the semiconductor device 100.

Referring now to FIG. 5, this figure is a cross-sectional view of the semiconductor device 100 of FIG. 4 after additional fabrication operations, according to embodiments. As shown in FIG. 5, a second ILD layer 112 is formed on the upper surfaces of the metal cap layer 110 and the dielectric cap 108. It should be appreciated that the second ILD layer 112 may comprise one or more suitable dielectric materials, and these materials may be the same or different as the materials of the first ILD layer 102.

Referring now to FIG. 6, this figure is a cross-sectional view of the semiconductor device 100 of FIG. 5 after additional fabrication operations, according to embodiments. As shown in FIG. 6, suitable patterning and material removal processes are performed on the second ILD layer 112 to expose a portion of the top surface of the metal cap layer 110. In certain examples, the width of the openings in the second ILD layer 112 may be less than a width of the bottom metal contact 106 and the width of the metal cap layer 110. Thus, less than the entire upper surface of the metal cap layer 110 is exposed after this processing step.

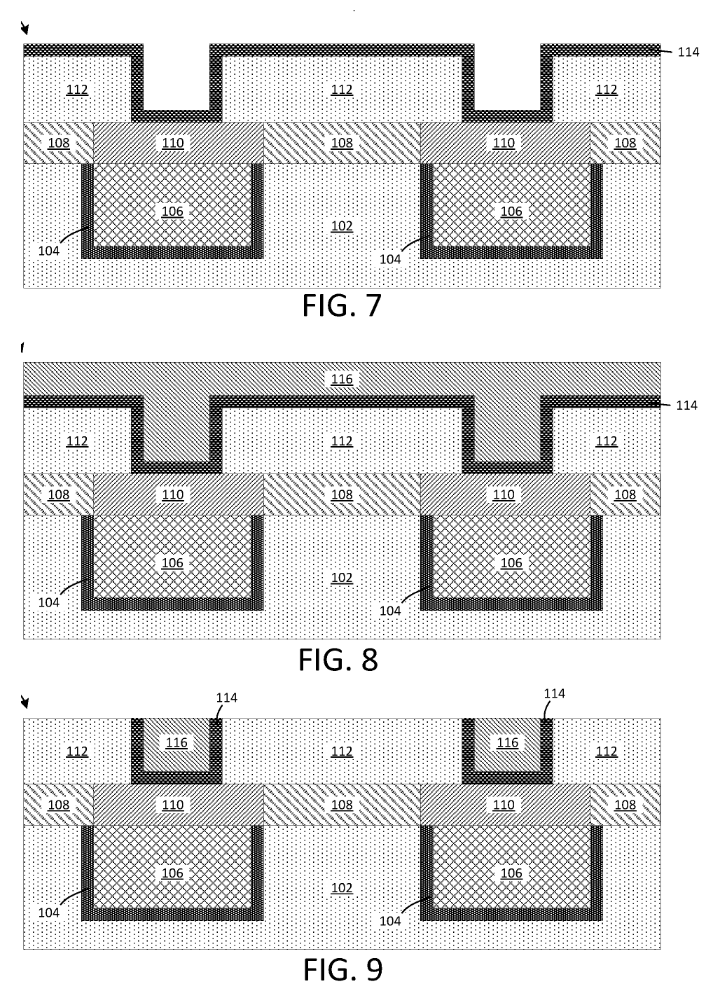

Referring now to FIG. 7, this figure is a cross-sectional view of the semiconductor device 100 of FIG. 6 after additional fabrication operations, according to embodiments. As shown in FIG. 7, after the patterning of the second ILD layer 112 a metal deposition step is performed to form a portion of the bottom electrode 114. A suitable amount of material (e.g., TiN) is deposited to cover the upper surface of the metal cap layer 110 as well as the sidewalls and top surfaces of the second ILD layer 112. In other examples, the bottom electrode 114 may comprise Nb, NbN, W, WN, Ta, TaN, Ti, Ru, Mo, Cr, V, Pd, Pt, Rh, Sc, ScN, Al and other high melting point metals or conductive metal nitrides, or any other suitable conductive material(s) for use in an electrode. In certain embodiments, only of a portion of the openings between adjacent portions of the second ILD layer are filled with the material of the bottom electrode 114.

Referring now to FIG. 8, this figure is a cross-sectional view of the semiconductor device 100 of FIG. 7 after additional fabrication operations, according to embodiments. As shown in FIG. 8, a dielectric fill layer 116 is deposited to fill in the remaining space of the openings between adjacent portions of the second ILD layer 112. In certain examples, as shown in FIG. 8, the dielectric fill layer 116 may initially be formed in excess so that a portion of the dielectric fill layer extends above the top surface of the bottom electrode 114. It should be appreciated that the dielectric fill layer 116 may comprise one or more suitable dielectric materials such as, for example, Al₂O₃. It should also be appreciated that the material(s) of the dielectric fill layer may be the same as or different from the materials of the first ILD layer 102 and/or the second ILD layer 112.

Referring now to FIG. 9, this figure is a cross-sectional view of the semiconductor device 100 of FIG. 8 after additional fabrication operations, according to embodiments. As shown in FIG. 9, a suitable material removal process (e.g., CMP) may be performed to remove any excess material of the dielectric fill layer 116 and to planarize the upper surface of the semiconductor device 100. The material removal process removes not only the excess material of the dielectric fill layer 116, but also the material of the bottom electrode 114 that was previously formed on the top surfaces of the second ILD layer 112. Thus, the upper surfaces of the second ILD layer are exposed after this material removal step.

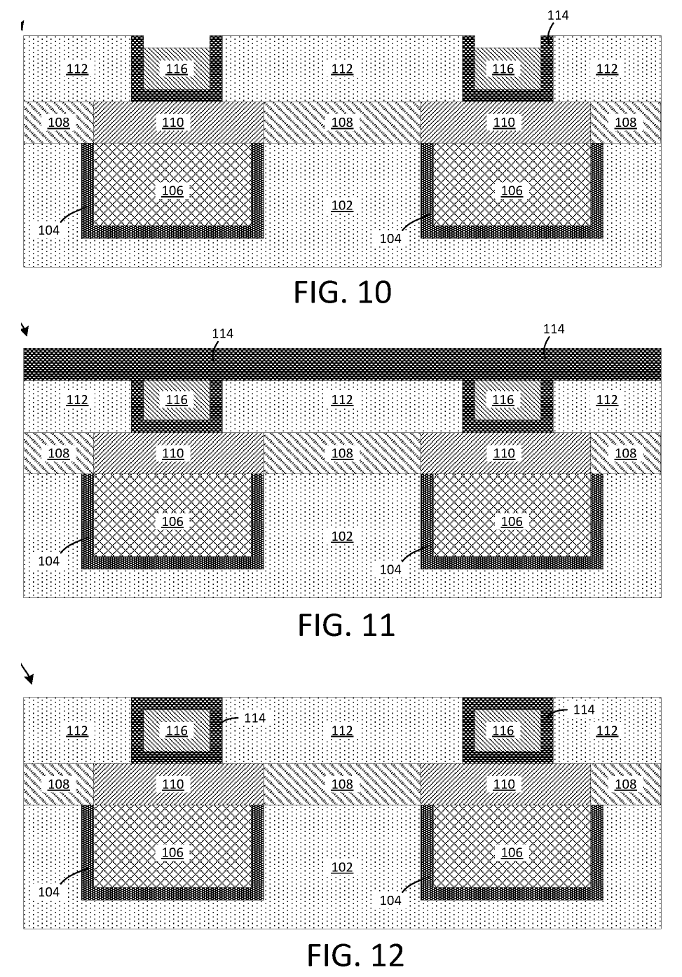

Referring now to FIG. 10, this figure is a cross-sectional view of the semiconductor device 100 of FIG. 9 after additional fabrication operations, according to embodiments. As shown in FIG. 10, a suitable material removal process is performed to recess a portion of the dielectric fill layer 116. As shown in FIG. 10, the level of the top surface of the dielectric fill layer 116 is now below the level of the top surface of the second ILD layer 112. This will allow for the subsequent formation of a top portion of the bottom electrode 114.

Referring now to FIG. 11, this figure is a cross-sectional view of the semiconductor device 100 of FIG. 10 after additional fabrication operations, according to embodiments. As shown in FIG. 11, additional material of the bottom electrode 114 is deposited to cover the second ILD layer 112 and the dielectric fill layer 116.

Referring now to FIG. 12, this figure is a cross-sectional view of the semiconductor device 100 of FIG. 11 after additional fabrication operations, according to embodiments. As shown in FIG. 12, a suitable material removal process (e.g., CMP) may be performed to remove any excess material of the additional portions of the bottom electrode 114 that are above the upper surface of the second ILD layer 112 and to planarize the upper surface of the semiconductor device 100. It should be appreciated that the presence of the dielectric fill layer 116 (or dielectric core) in the middle of the bottom electrode 114 may aid in the CMP step because there is less top surface area of the bottom electrode 114, and this may help reduce the possibility of dishing or cupping of the bottom electrode 114 during the CMP process (i.e., relative to a situation where there is no dielectric fill layer 116 and the bottom electrode 114 is a solid metal structure). In certain examples, the shape of the bottom electrode 114 is cylindrical with a cylindrically shaped dielectric fill layer 116 formed therein.

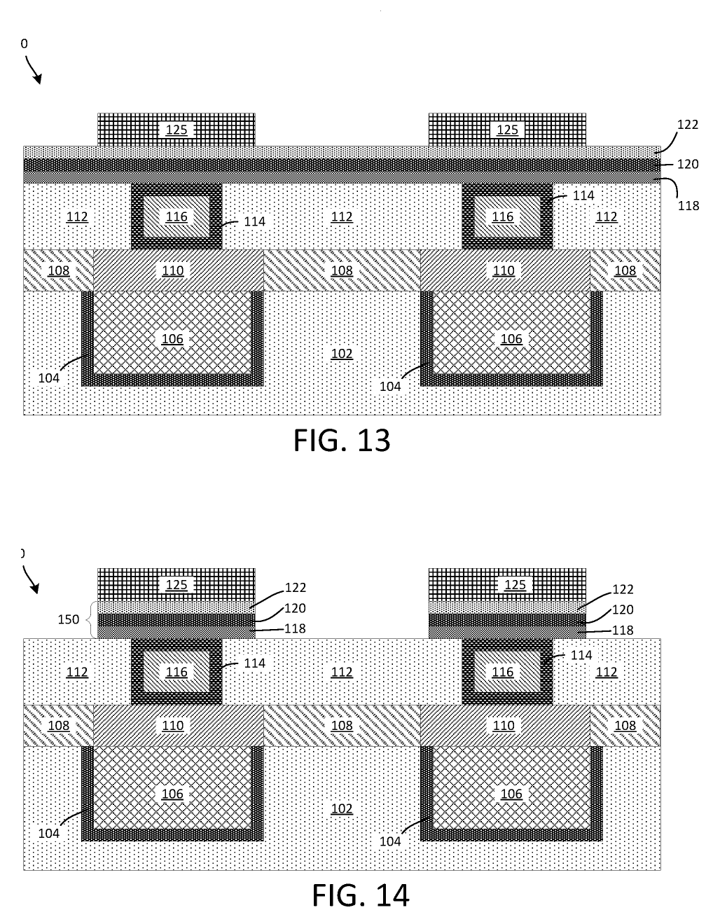

Referring now to FIG. 13, this figure is a cross-sectional view of the semiconductor device 100 of FIG. 12 after additional fabrication operations, according to embodiments. As shown in FIG. 13, the active layers of the MRAM device (i.e., the MTJ stack 150) are formed on top of the bottom electrode 114. The MTJ stack 150 may include multiple layers such as, for example, multiple magnetic layers separated by an insulating layer. In certain embodiments, the MTJ stack 150 includes a reference layer 118, a tunnel barrier layer 120, and a magnetic free layer 122. In general, the magnetic free layers have a magnetic moment or magnetization that can be flipped. In certain embodiments, the tunnel barrier layer 120 is a barrier, such as a thin insulating layer or electric potential, between two electrically conducting materials. Electrons (or quasiparticles) pass through the tunnel barrier by the process of quantum tunneling. In certain embodiments, the tunnel barrier layer 120 includes at least one sublayer composed of MgO. The reference layer 122 (or fixed layer) may, for example, be annealed in a magnetic field to set a polarization state of the reference layer 118 in the MTJ stack 150. In certain embodiments, each layer of the MTJ stack 150 may have a thickness less than an angstrom to a thickness of several angstroms or nanometers. Examples of typical materials in an MTJ stack 150 can include MgO, MgAlOₓ, AlOₓ, etc. for the tunnel barrier layer 120, CoFeB for the free layer 122, and a plurality of layers comprised of different materials for the reference layer 118. It should be appreciated that the MRAM stack 150 is not limited to these materials, or the layers described above. That is, the MRAM stack 150 can be composed of any known stack of materials used in MRAM devices. In certain embodiments, the MTJ stack 150 can have a combination of ferro and anti-ferromagnetic metals such as Co/Fe/Ni, other metals such as Pt/Ir as well as B. Moreover, it should be appreciated that the MTJ stack 150 may include additional layers, omit certain layers, and each of the layers may include any number of sublayers. It should be appreciated that this MRAM stack 150 structure shown in FIG. 13 is only an example, and any other suitable MRAM stack 150 structure known to one of skill in the art may be utilized.

After the formation of the MTJ stack 150, a hardmask 125 is formed thereon to allow for the subsequent patterning of the MTJ pillar. In certain examples, the material of the hardmask 125 may be TaN or any other suitable material(s). For example, the hardmask 125 may include one or more of the following materials: TaN, WCN; TiN; TaAlN; WN; TEOS; low-κ and ULK etc. The pattern of the hardmask 125 is transferred to the magnetic tunnel junction (MTJ) stack (i.e., the reference layer 118, the tunnel barrier layer 120, and the magnetic free layer 122), which is etched to create the MTJ pillars. In one example, a two-step material removal process is used to form the MTJ pillars.

Referring now to FIG. 14, this figure is a cross-sectional view of the semiconductor device 100 of FIG. 13 after additional fabrication operations, according to embodiments. As shown in FIG. 14, patterning is performed using the hardmask 125 as a mask to form the MTJ stack 150 pillars (i.e., the free layer 118, the tunnel barrier layer 120, and the reference layer 122). In certain examples, the MTJ stack 150 pillars have a width that is wider than the width of the bottom electrode 114. During the MTJ patterning process, due the presence of the second ILD layer 112, there is no risk of re-sputtering of the materials of the free layer 118, the tunnel barrier layer 120, or the reference layer 122 onto the bottom electrode 114. This may decrease the potential for electrical shorting between the various layers of the MTJ stack 150. Then, the hardmask 125 is removed (not shown in FIG. 14) with any suitable material removal process.

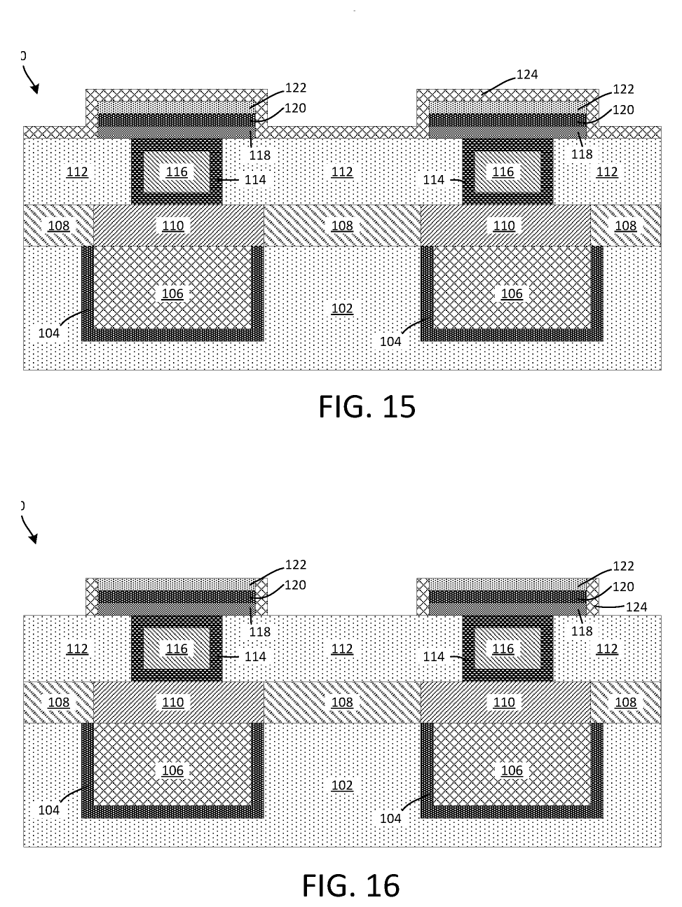

Referring now to FIG. 15, this figure is a cross-sectional view of the semiconductor device 100 of FIG. 14 after additional fabrication operations, according to embodiments. As shown in FIG. 15, a dielectric encapsulation layer 124 is deposited over the entire surface of the semiconductor device 100 to cover the second ILD layer 112 and the MTJ stack 150. In certain examples, the dielectric encapsulation layer 124 may comprise SiN or any other suitable dielectric material(s).

Referring now to FIG. 16, this figure is a cross-sectional view of the semiconductor device 100 of FIG. 15 after additional fabrication operations, according to embodiments. As shown in FIG. 16, an etch back process is performed to remove all horizontal portions of the dielectric encapsulation layer 124. Thus, the only portions of the dielectric encapsulation layer 124 cover the sidewalls of the MRAM stack (i.e., the free layer 118, the tunnel barrier layer 120, and the reference layer 122).

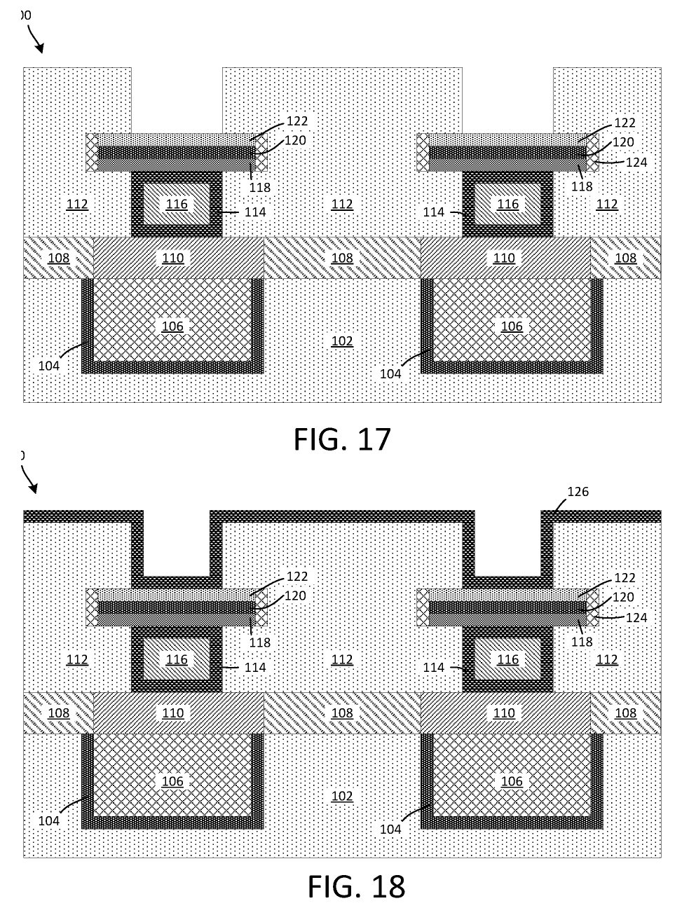

Referring now to FIG. 17, this figure is a cross-sectional view of the semiconductor device 100 of FIG. 16 after additional fabrication operations, according to embodiments. As shown in FIG. 17, additional material of the second ILD layer 112 is deposited onto the semiconductor device 100 to increase the overall thickness of this layer and to fill in the spaces between adjacent MTJ stacks 150. It should be noted that because the second ILD layer 112 is formed in separate steps (see, FIGS. 5 and 17), the thickness of the material added to the second ILD layer 112 has a low aspect ratio (i.e., the thickness of the material added is low compared to the width of the material added). This low aspect ratio for the material deposition is beneficial because it reduces or eliminates the possibility of creating ILD voids. As mentioned above, a potential problem with forming thick high aspect ratio ILD layer (e.g., in one step) is that ILD voids can be created which lead to potential issues with electrical shorting between the electrodes of adjacent MRAM stacks. Then, as shown in FIG. 17, suitable patterning and material removal processes are once again performed on the second ILD layer 112 to expose a portion of the top surface of the free layer 122. In certain examples, the width of the openings in the second ILD layer 112 may be less than a width of the bottom metal contact 106 and less than the width of the metal cap layer 110. Thus, less than the entire upper surface of the free layer 122 is exposed after this processing step. In certain examples, the size of the openings formed in the second ILD layer 112 may be the same as the size of the openings that were formed in the second ILD layer 112 as shown in FIG. 6. This will allow for the top electrode to be formed to roughly the same size as the bottom electrode 114.

Referring now to FIG. 18, this figure is a cross-sectional view of the semiconductor device 100 of FIG. 17 after additional fabrication operations, according to embodiments. As shown in FIG. 18, after the second patterning of the second ILD layer 112 a metal deposition step is performed to form a portion of the top electrode 126. A suitable amount of material (e.g., TiN) is deposited to cover the upper surface of the metal free layer 122 as well as the sidewalls and top surfaces of the second ILD layer 112. In other examples, the top electrode 126 may comprise Nb, NbN, W, WN, Ta, TaN, Ti, Ru, Mo, Cr, V, Pd, Pt, Rh, Sc, Al and other high melting point metals or conductive metal nitrides, or any other suitable conductive material(s) for use in an electrode. In certain embodiments, only of a portion of the openings between adjacent portions of the second ILD layer 112 are filled with the material of the top electrode 126.

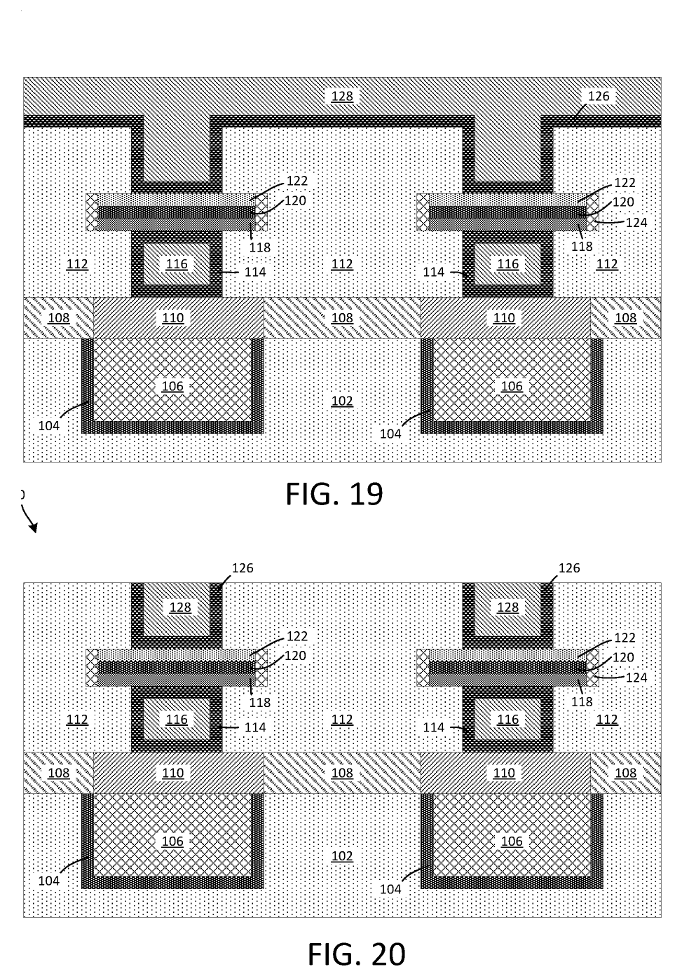

Referring now to FIG. 19, this figure is a cross-sectional view of the semiconductor device 100 of FIG. 18 after additional fabrication operations, according to embodiments. As shown in FIG. 19, a second dielectric fill layer 128 is deposited to fill in the remaining space of the openings between adjacent portions of the second ILD layer 112. In certain examples, as shown in FIG. 19, the second dielectric fill layer 128 may initially be formed in excess so that a portion of the second dielectric fill layer 128 extends above the top surface of the top electrode 126. It should be appreciated that the second dielectric fill layer 128 may comprise one or more suitable dielectric materials such as, for example, Al₂O₃. It should also be appreciated that the material(s) of the second dielectric fill layer 128 may be the same as or different from the materials of the first ILD layer 102, the dielectric fill layer 116 and/or the second ILD layer 112.

Referring now to FIG. 20, this figure is a cross-sectional view of the semiconductor device 100 of FIG. 19 after additional fabrication operations, according to embodiments. As shown in FIG. 20, a suitable material removal process (e.g., CMP) may be performed to remove any excess material of the second dielectric fill layer 128 and to planarize the upper surface of the semiconductor device 100. The material removal process removes not only the excess material of the second dielectric fill layer 128, but also the material of the top electrode 126 that was previously formed on the top surfaces of the second ILD layer 112. Thus, the upper surfaces of the second ILD layer 112 are exposed after this material removal step.

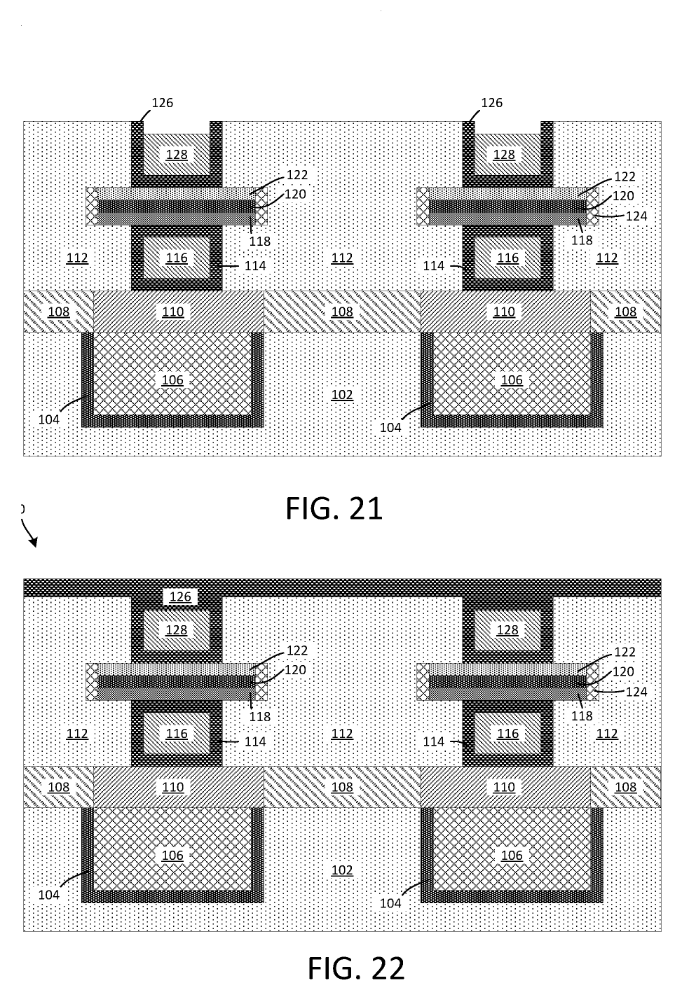

Referring now to FIG. 21, this figure is a cross-sectional view of the semiconductor device 100 of FIG. 20 after additional fabrication operations, according to embodiments. As shown in FIG. 21, a suitable material removal process such at etching is performed to recess a portion of the second dielectric fill layer 128. As shown in FIG. 21, the level of the top surface of the second dielectric fill layer 128 is now below the level of the top surface of the second ILD layer 112. This will allow for the subsequent formation of a top portion of the top electrode 126.

Referring now to FIG. 22, this figure is a cross-sectional view of the semiconductor device 100 of FIG. 21 after additional fabrication operations, according to embodiments. As shown in FIG. 22, additional material of the top electrode 126 is deposited to cover the second ILD layer 112 and the second dielectric fill layer 128.

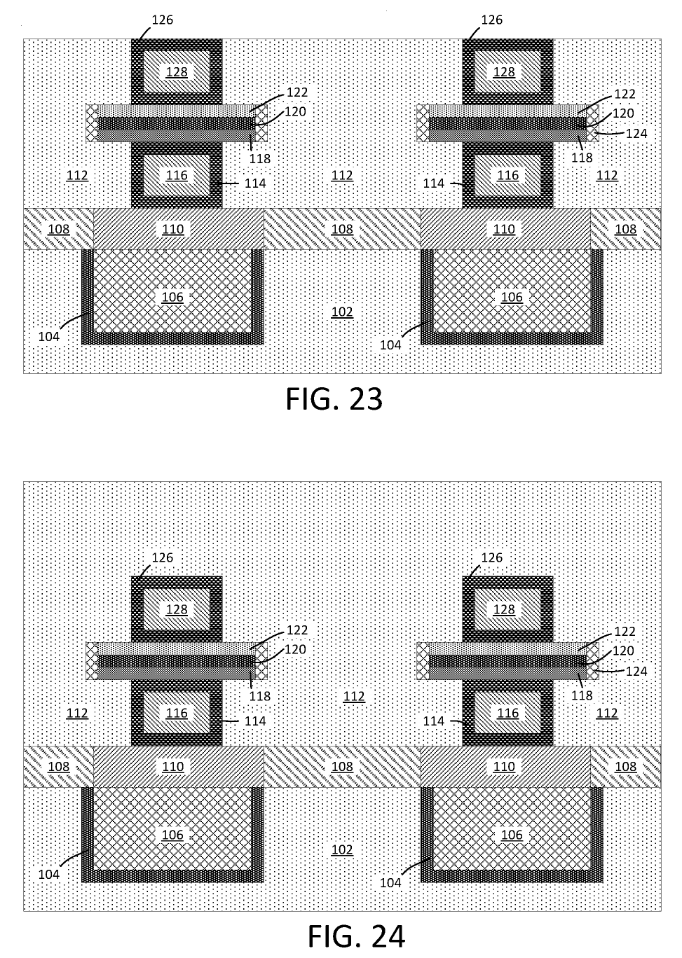

Referring now to FIG. 23, this figure is a cross-sectional view of the semiconductor device 100 of FIG. 22 after additional fabrication operations, according to embodiments. As shown in FIG. 23, a suitable material removal process (e.g., CMP) may be performed to remove any excess material of the additional portions of the top electrode 126 that are above the upper surface of the second ILD layer 112 and to planarize the upper surface of the semiconductor device 100. In certain examples, the shape of the top electrode 126 is cylindrical with a cylindrically shaped second dielectric fill layer 128 formed therein.

Referring now to FIG. 24, this figure is a cross-sectional view of the semiconductor device 100 of FIG. 23 after additional fabrication operations, according to embodiments. As shown in FIG. 24, further additional material of the second ILD layer 112 is deposited to cover the top electrode 126. Similar to the process described above with respect to FIG. 17, the thickness of the material added to the second ILD layer 112 has a low aspect ratio (i.e., the thickness of the material added is low compared to the width of the material added). This low aspect ratio for the material deposition is beneficial because it reduces or eliminates the possibility of creating ILD voids. Thus, as described above with respect to FIGS. 5, 17, and 24, the entire thickness of the second ILD layer 112 is formed in three separate processing operations. Accordingly, because the aspect ratio of the material added to the second ILD layer 112 in each of these three steps is low, there is a reduced risk of creating ILD voids. Thus, the risk of electrical shorting between components (e.g., the top electrodes 126) of adjacent MRAM stacks may be reduced or eliminated.

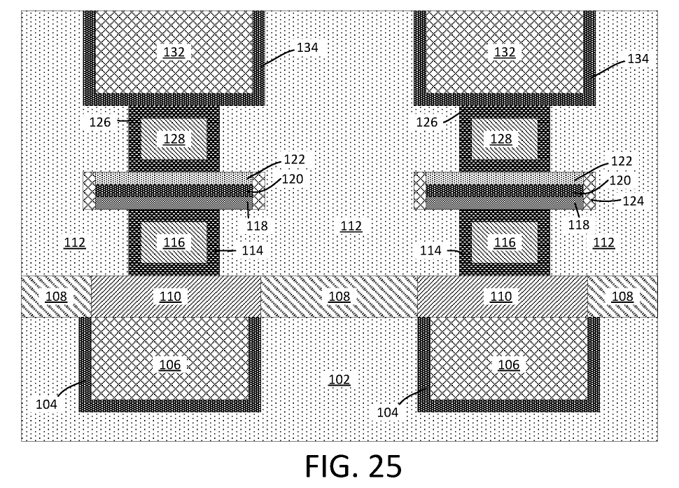

Referring now to FIG. 25, this figure is a cross-sectional view of the semiconductor device 100 of FIG. 24 after additional fabrication operations, according to embodiments. As shown in FIG. 25, a suitable combination of patterning and material removal processes are performed to form top metal contact holes (not shown in FIG. 25). Then, as shown in FIG. 1, a top barrier layer 134 is first formed in the top metal contact holes. The top barrier layer 134 may comprise, for example, Ta or TaN. Then, a top metal contact 132 (or top metal layer) is deposited on the top barrier layer 134 and fills in the remainder of the top metal contact hole. This top metal contact 132 may be included in one of the FEOL, MOL or BEOL layers. In certain examples, the top metal contact 132 (e.g., an M1 level interconnect wire) may include, Cu, Co, Nb, NbN, W, WN, Ta, TaN, Ti, TiN, Ru, Mo, Cr, V, Pd, Pt, Rh, Sc, Al and other metals or conductive metal nitrides. It should be appreciated that the interconnect structure shown in FIG. 1 is merely one example, and any other suitable interconnect structure (e.g., number of layers, size, number of contacts, etc.) may be used. Then, in certain examples, and optional material removal process such as chemical mechanical planarization (CMP) may be performed to planarize the surface of the semiconductor device 100.

In certain embodiments, a semiconductor device includes an MRAM pillar structure with bottom and top electrodes having a dielectric core, thus enabling a void-free ILD fille layer between pillars. This structure exhibits no ILD voids between MRAM pillars because only low aspect ratio features need to be filled with ILD.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a memory including
a bottom electrode,
a magnetic tunnel junction (MTJ) stack on the bottom electrode, and
an upper electrode on the MTJ stack,
wherein the bottom electrode and the top electrode each include a dielectric core.

2. The semiconductor device according to claim 1, wherein a width of the MTJ stack is greater than a width of bottom electrode and greater than a width of the top electrode.

3. The semiconductor device according to claim 1, wherein the bottom electrode and the top electrode have a cylindrical shape.

4. The semiconductor device according to claim 3, wherein the dielectric cores have a cylindrical shape.

5. The semiconductor device according to claim 1, further comprising a dielectric encapsulation layer formed to cover sidewalls of the MTJ stack.

6. The semiconductor device according to claim 1, further comprising a dielectric fill layer formed around the memory and that directly contacts the top electrode and the bottom electrode.

7. The semiconductor device according to claim 1, further comprising a bottom metal contact electrically connected to the bottom electrode, and a top metal contact electrically connected to the top electrode.

8. The semiconductor device according to claim 7, further comprising a metal cap layer between the bottom metal contact and the bottom electrode.

9. A semiconductor device comprising:
a memory including
a bottom electrode,
a magnetic tunnel junction (MTJ) stack on the bottom electrode, and
an upper electrode on the MTJ stack; and
wherein a width of the MTJ stack is greater than a width of bottom electrode and greater than a width of the top electrode.

10. The semiconductor device according to claim 9, wherein the bottom electrode and the top electrode each include a dielectric core.

11. The semiconductor device according to claim 10, wherein the bottom electrode and the top electrode have a cylindrical shape.

12. The semiconductor device according to claim 11, wherein the dielectric cores have a cylindrical shape.

13. The semiconductor device according to claim 9, further comprising a dielectric encapsulation layer formed to cover sidewalls of the MTJ stack.

14. The semiconductor device according to claim 9, further comprising a dielectric fill layer formed around the memory, the dielectric fill layer directly contacting the top electrode and the bottom electrode.

15. The semiconductor device according to claim 9, further comprising a bottom metal contact electrically connected to the bottom electrode, and a top metal contact electrically connected to the top electrode.

16. A method of manufacturing a semiconductor device, the method comprising:
forming a first portion of a dielectric fill layer;
forming a bottom electrode in the first portion of the dielectric fill layer;
forming a magnetic tunnel junction (MTJ) stack on the bottom electrode;
forming a second portion of the dielectric fill layer on the first portion of the dielectric fill layer and on the MTJ stack;
forming a top electrode on the MTJ stack in the second portion of the dielectric fill layer; and
forming a third portion of the dielectric fill layer on the second portion of the dielectric fill layer and on the top electrode.

17. The method according to claim 16, further comprising forming a dielectric encapsulation layer that covers sidewalls of the MTJ stack.

18. The method according to claim 16, further comprising forming a dielectric core in the bottom electrode and the top electrode.

19. The method according to claim 16, further comprising forming a top metal contact on the top electrode in the third portion of the dielectric fill layer.

20. The method according to claim 16, wherein a width of the MTJ stack is greater than a width of bottom electrode and greater than a width of the top electrode.
